(19) United States
(12) Patent Application Publication
(10) Pub. No.: US 2025/0105714 A1
(43) Pub. Date: Mar. 27, 2025

(54) MAGNETIC GAP LENGTH ESTIMATING DEVICE, DRIVING DEVICE FOR ELECTRIC ROTATING MACHINE, ELECTRIC ROTATING MACHINE SYSTEM, AND MAGNETIC GAP LENGTH ESTIMATING METHOD

(71) Applicants: Mitsubishi Electric Corporation, Tokyo (JP); National University Corporation YOKOHAMA National University, Yokohama-shi, Kanagawa (JP)

(72) Inventors: Kodai OKAZAKI, Tokyo (JP); Kan AKATSU, Yokohama-shi, Kanagawa (JP)

(73) Assignees: Mitsubishi Electric Corporation, Tokyo (JP); National University Corporation YOKOHAMA National University, Yokohama-shi, Kanagawa (JP)

(21) Appl. No.: 18/832,111

(22) PCT Filed: Feb. 9, 2022
(86) PCT No.: PCT/JP2022/005059

§ 371 Date: Jul. 23, 2024

(51) Int. Cl. H02K 15/165; G01R 31/34; H02K 21/14

(52) U.S. Cl. CPC H02K 15/165; G01R 31/343; H02K 21/14

(57) ABSTRACT

A magnetic gap length estimating device of the present application includes a voltage acquisition circuitry to acquire a line-to-line induced voltage induced in connection lines between an inverter and an electric rotating machine with a plurality of groups and phases, an estimation information creation circuitry to create estimation information for estimating a magnetic gap length from the waveform of the line-to-line induced voltage when the electric rotating machine is rotated in an unloaded state, and an instantaneous gap length estimation circuitry to estimate an instantaneous magnetic gap length from an instantaneous value of the line-to-line induced voltage and the estimation information.

### TECHNICAL FIELD

The present application relates to a magnetic gap length estimating device, a driving device for an electric rotating machine, an electric rotating machine system, and a magnetic gap length estimating method.

### BACKGROUND ART

In an electric rotating machine such as an electric motor, when an eccentricity such as a static eccentricity, which is a deviation between a central axis of a rotor and a central axis of a stator, or a dynamic eccentricity, which is a deviation between a shape center and a rotation center of the rotor, occurs, a magnetic gap length between the rotor and the stator varies, and a magnetic unbalance occurs. Since the magnetic unbalance causes low-frequency vibration, noise, and the like, the electric rotating machine is required to suppress the eccentricity.

The eccentricity occurs in a manufacturing process of the electric rotating machine, such as a process of assembling the rotor, a process of inserting the rotor into the stator, and a process of fixing the rotary shaft with a bracket after the insertion. The eccentricity also occurs due to a defect occurring in a bearing portion of the rotor during driving of the electric rotating machine. Therefore, it is difficult to completely eliminate the variation of the magnetic gap length caused by the eccentricity in the electric rotating machine, and a technique for detecting and correcting the eccentricity in the manufacturing process and a technique for detecting the eccentricity by analyzing the current and voltage of the electric rotating machine during driving and for suppressing the influence are required.

Therefore, in an electric motor to which a magnetic bearing system is applied, a technique for estimating an eccentric amount by detecting a circulating current flowing through a parallel connection has been proposed (for example, refer to Patent Document 1). Further, in a bearingless motor, a technique for estimating an eccentric amount by detecting a three-phase induced voltage using a position control winding has been proposed (for example, refer to Patent Document 2).

### PRIOR ART DOCUMENT

### Patent Document

Patent Document 1: International Publication No. WO2015/019463 (paragraphs 0024 to 0027, FIG. 2)
Patent Document 2: Japanese Patent Application Laid-Open No. H11-142104 (paragraphs 0042 to 0045, FIG. 1 to

### SUMMARY OF INVENTION

### Problems to be Solved by Invention

However, in order to detect the circulating current flowing through the parallel connection, equipment such as a current sensor for detecting the circulating current is essential, and when this technique is used for the eccentricity inspection during the manufacturing process, there is a problem in that this leads to an increase in the size of the inspection apparatus. In addition, equipment such as a current load is required in order to detect the three-phase induced voltage. Therefore, when this technique is used for the eccentricity inspection during the manufacturing process, there is a problem in that the size of the inspection apparatus increases. Further, when these techniques are applied to a drive system of an electric rotating machine, additional equipment is required, which leads to an increase in the size of the system.

The present application discloses a technique for solving the above-described problems, and an object of the present application is to provide a magnetic gap length estimating device, a magnetic gap length estimating method, a driving device for an electric rotating machine, or a magnetic gap length estimating method that are capable of estimating a magnetic gap length without requiring additional equipment and of suppressing vibration and noise caused by variation in the magnetic gap length.

### Means for Solving the Problems

A magnetic gap length estimating device disclosed in the present application includes a voltage acquisition unit to acquire a line-to-line induced voltage induced in connection lines between an electric rotating machine having a plurality of groups of coils when coils of a plurality of phases are set as one group and an inverter for driving the electric rotating machine, an estimation information creation unit to create estimation information for estimating a magnetic gap length from a waveform of the line-to-line induced voltage when the electric rotating machine is rotated in an unload state, and an instantaneous gap length estimation unit to estimate the magnetic gap length at an instantaneous time from an instantaneous value of the line-to-line induced voltage and the estimation information.

A magnetic gap length estimating method disclosed in the present application includes steps of rotating the electric rotating machine having the plurality of groups of coils when coils of the plurality of phases are set as one group, by one or more rotations at a constant rotation speed in an unloaded state, acquiring a waveform of the line-to-line induced voltage induced in the connection lines between the electric rotating machine and the inverter for driving the electric rotating machine, creating the estimation information for estimating the magnetic gap length, and estimating the magnetic gap length at an instantaneous time from an instantaneous value of the line-to-line induced voltage and the estimation information.

### Advantageous Effect of Invention

According to the magnetic gap length estimating device or the magnetic gap length estimating method disclosed in the present application, the magnetic gap length of the electric rotating machine is estimated on the basis of a result by comparing line-to-line induced voltages of connection lines between the inverter and the electric rotating machine with the estimation information based on the characteristics of the electric rotating machine. Therefore, the magnetic gap length can be estimated without requiring additional equipment such as a current sensor and a current load, and vibration and noise caused by the variation in the magnetic gap length can be suppressed.

### BRIEF DESCRIPTION OF THE DRAWINGS

FIG. 1 is a block diagram for describing a configuration of a magnetic gap length estimating device according to Embodiment 1.

FIG. 2 is a block diagram for describing a configuration of a magnetic gap length estimating unit of the magnetic gap length estimating device according to Embodiment 1.

FIG. 3 is a plan view showing a configuration of a stator of the electric rotating machine to be measured by the magnetic gap length estimating device according to Embodiment 1.

FIG. 4 is a connection diagram of the stator of the electric rotating machine to be measured by the magnetic gap length estimating device according to Embodiment 1.

FIG. 5 is a schematic diagram showing a state in which dynamic eccentricity occurs in the electric rotating machine to be measured by the magnetic gap length estimating device according to Embodiment 1.

FIG. 6 is a flowchart for describing an entire process in a magnetic gap length estimating method according to Embodiment 1.

FIG. 7 is a flowchart for describing a pre-processing phase in the magnetic gap length estimating method according to Embodiment 1.

FIG. 8 is a flowchart for describing a detection phase in the magnetic gap length estimating method according to Embodiment 1.

FIG. 9A and FIG. 9B are a waveform diagram and a diagram in the form of a bar graph showing an amplitude for each order by Fourier transformation, for describing an operation of a step of extracting a fundamental wave component and L±P-th order harmonic components of a line-to-line voltage in the magnetic gap length estimating method according to Embodiment 1.

FIG. 10 is a diagram in the form of a line graph showing a relationship between a dynamic eccentricity amount and a harmonic component, for describing an operation of a step of estimating a variation amount of a magnetic gap length in the magnetic gap length estimating method according to Embodiment 1.

FIG. 11 is a diagram in the form of a line graph for describing an operation of estimating a displacement direction with respect to a magnetic pole position of a rotor in the magnetic gap length estimating method according to Embodiment 1.

FIG. 12A and FIG. 12B are a waveform diagram of line-to-line voltages between different phases of the same group and a diagram showing a Lissajous curve, for describing an operation of a step of creating the Lissajous curve in the magnetic gap length estimating method according to Embodiment 1.

FIG. 13A and FIG. 13B are a waveform diagram of line-to-line voltages between the same phases of different groups and a diagram showing a Lissajous curve for describing the operation of the step of creating the Lissajous curve in the magnetic gap length estimating method according to Embodiment 1.

FIG. 14A and FIG. 14B are a diagram in the form of a line graph showing a relationship between an absolute displacement direction and an angle of a Lissajous curve and a diagram showing a locus of an angle of the Lissajous curve depending on a change in the displacement direction, for describing the operation of the step of creating the Lissajous curve in the magnetic gap length estimating method according to Embodiment 1.

FIG. 15 is a plan view of a stator showing a configuration of another electric rotating machine to be measured by the magnetic gap length estimating device according to Embodiment 1.

FIG. 16 is a block diagram for describing a configuration of a driving device for an electric rotating machine and an electric rotating machine system according to Embodiment 2.

FIG. 17 is a block diagram for describing a configuration of a magnetic gap length estimating device according to Embodiment 3.

FIG. 18 is a plan view showing a configuration of a stator of an electric rotating machine to be measured by a magnetic gap length estimating device according to Embodiment 3.

FIG. 19 is a connection diagram of the stator of the electric rotating machine to be measured by the magnetic gap length estimating device according to Embodiment 3.

FIG. 20 is a block diagram for describing a configuration of a driving device for an electric rotating machine and an electric rotating machine system according to Embodiment 4.

FIG. 21 is a block diagram for describing a configuration of a magnetic gap length estimating device according to Embodiment 5.

FIG. 22 is a plan view showing a configuration of a stator of an electric rotating machine to be measured by the magnetic gap length estimating device according to Embodiment 5.

FIG. 23 is a plan view of a stator showing a configuration of another electric rotating machine to be measured by the magnetic gap length estimating device according to Embodiment 5.

FIG. 24 is a block diagram for describing a configuration of a driving device for an electric rotating machine and an electric rotating machine system according to Embodiment 6.

FIG. 25 is a block diagram showing an example of a hardware configuration of the magnetic gap length estimating device or the driving device for the electric rotating machine according to each embodiment.

### MODE FOR CARRYING OUT INVENTION

Hereinafter, a magnetic gap length estimating device, a magnetic gap length estimating method, a driving device for an electric rotating machine, and a magnetic gap estimation method according to embodiments for carrying out the present application will be described in detail with reference to the drawings. In the drawings, the same reference numerals denote the same or corresponding parts.

### Embodiment 1

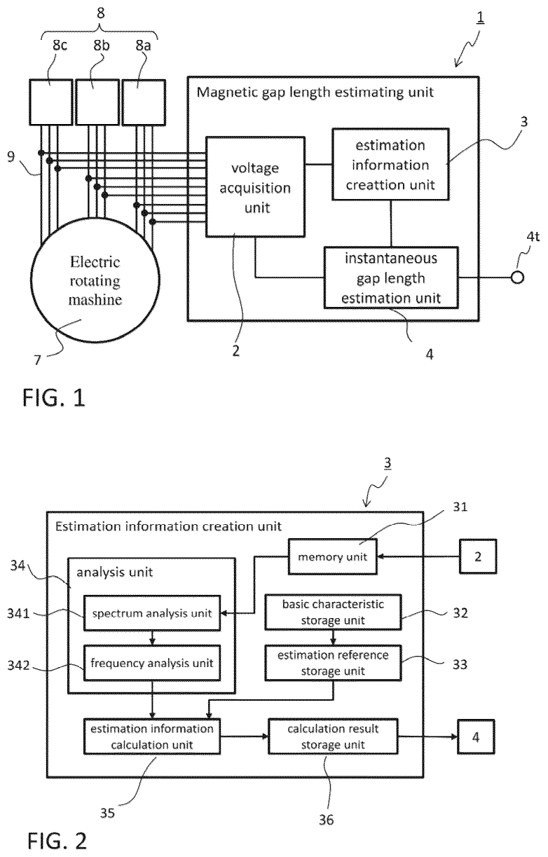

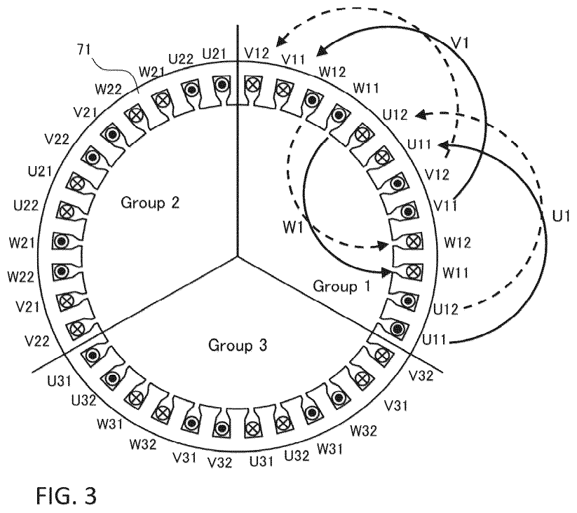

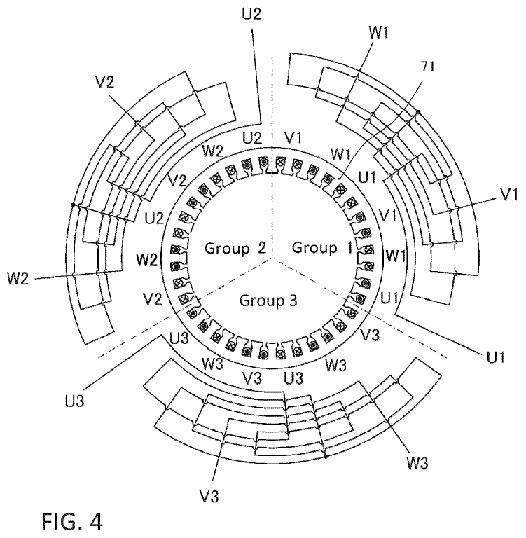

FIG. 1 to FIG. 4 are diagrams for describing a configuration and an operation of the magnetic gap length estimating device according to Embodiment 1, FIG. 1 is a block diagram including the electric rotating machine to be measured and an inverter for describing a configuration of the magnetic gap length estimating device, and FIG. 2 is a block diagram for describing a configuration of a magnetic gap length estimating unit of the magnetic gap length estimating device. FIG. 3 is a plan view perpendicular to an axis, showing a configuration of a stator of the electric rotating machine to be measured by the magnetic gap length estimating device, and FIG. 4 is a connection diagram corresponding to FIG. 3 in the stator of the electric rotating machine.

### <Magnetic Gap Length Estimating Device>

As shown in FIG. 1, a magnetic gap length estimating device 1 according to Embodiment 1 is intended for measurement of an electric rotating machine 7 driven by three-group three-phase inverters 8 including three inverters 8a to 8c. A gap length is estimated on the basis of line-to-line voltages of connection lines 9 between the inverter 8 and the electric rotating machine 7 without using additional equipment such as a current load. For this purpose, a voltage acquisition unit 2 that acquires line-to-line voltages of nine connection lines 9, an estimation information creation unit 3 that creates estimation information for estimating a magnetic gap length, and an instantaneous gap length estimation unit 4 that estimates an instantaneous magnetic gap length on the basis of the line-to-line voltages and the estimation information acquired during driving of the electric rotating machine 7 are provided.

The instantaneous gap length estimation unit 4 estimates an instantaneous magnetic gap length during driving on the basis of the line-to-line voltages acquired by the voltage acquisition unit 2 during the driving operation of the electric rotating machine 7 and the estimation information created in advance by the estimation information creation unit 3. The instantaneous gap length estimation unit 4 has an external output terminal 4t for outputting information of the estimated magnetic gap length, and for example, by connecting an external monitor to the external output terminal 4t, a state of the magnetic gap can be visualized.

The estimation information generation unit 3 is roughly divided into an information acquisition and storage part of acquiring and storing information necessary for the estimation, a calculation part for analyzing the acquired information and the stored information to calculate the gap length, and an output part for storing and outputting the calculation result. As shown in FIG. 2, the information acquisition and storage part includes a memory unit 31 that stores data transmitted from the voltage acquisition unit 2, a basic characteristic storage unit 32 that stores basic characteristics of the electric rotating machine 7, and an estimation reference storage unit 33 that stores estimation reference data for estimating the magnetic gap length.

The calculation part includes an analysis unit 34 that extracts amplitudes and phases of a fundamental wave component and L±P-th order harmonic components of the line-to-line induced voltages on the basis of data transmitted from the memory unit 31, and an estimation information calculation unit 35 that calculates the estimation information on the basis of data extracted by the analysis unit 34. Further, the output part includes a calculation result storage unit 36 that stores the estimation information estimated by the estimation information calculation unit 35 and outputs the estimation information to the instantaneous gap length estimation unit 4 as necessary.

The basic characteristic storage unit 32 stores specifications such as dimensional specifications and a standard rotational speed of the electric rotating machine 7 to be measured. The estimation reference storage unit 33 stores estimation reference data necessary for estimating the magnetic gap length. The estimation reference data is, for example, a relationship between a line-to-line unloaded induced voltage and the magnetic gap length of the electric rotating machine 7 to be measured. The estimation reference data is obtained in advance by measurement or calculated by theoretical calculation. Here, the line-to-line unloaded induced voltage is a voltage induced between coils when an armature is rotated at a rated rotational speed in an unloaded state in which no current is applied to the armature.

The analysis unit 34 includes a spectrum analysis unit 341 that converts data acquired from the memory unit 31 into amplitude and phase information for each of frequencies, and a frequency analysis unit 342 that extracts the amplitudes and phases of the fundamental wave component and the L±P-th harmonic components of the line-to-line induced voltages from the amplitude and phase for each of the frequencies. The spectrum analysis unit 341 performs conversion into information on amplitudes and phases using, for example, a fast Fourier transform (FFT) algorithm. However, another algorithm may be used as long as the algorithm can perform similar spectrum analysis.

### <Basic Structure of Electric Rotating Machine>

Before describing the operation of the magnetic gap length estimating device 1 according to the present embodiment, the electric rotating machine 7 to be measured will be described. As shown in FIG. 3, the electric rotating machine 7 includes a stator 71 with a 6-pole 36-slot configuration n which a three-group three-phase inverter drive is assumed. The stator 71 has a configuration in which coils not denoted by reference numerals are independently wound in three groups of a group 1, a group 2, and a group 3, and the respective groups are separately disposed in the circumferential direction of the stator 71 with a phase difference of 360/3 (=120) degrees as a mechanical angle.

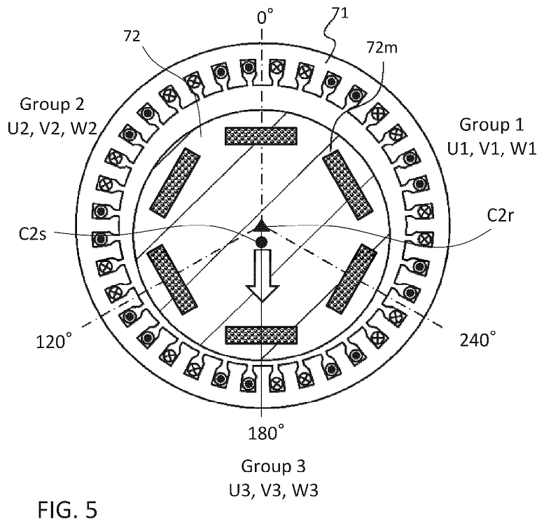

Further, in FIG. 3, the direction of the current flowing through each coil is indicated by two kinds of symbols. A symbol in which a cross mark (x) is put in a circle (∘) indicates a direction in which the current flows from the front side to the back side of the paper, and a symbol in which a black circle (●) is put in a circle indicates a direction in which the current flows from the back side to the front side of the paper. Note that, in FIG. 3, a rotor 72 (FIG. 5) is omitted from the figure.

The electric rotating machine 7 to be measured by the magnetic gap length estimating device 1 according to Embodiment 1 includes the stator 71 in a distributed winding structure in which a coil is arranged across several slots. Each of the three groups is composed of three phases, namely U, V and W phases, and each phase is constituted by two coils. For example, U1 indicating the U-phase coil of the group 1 has two coils, U11 and U12.

In FIG. 3, the winding direction of each coil of the group 1 is indicated by an arrow. The winding direction of each coil of the group 2 and the group 3 is the same as that of the group 1. The coils in each group are wound continuously in the circumferential direction in the order of U, W, and V phase. For example, in the group 1, U11, U12, W11, W12, V11, and V12 are arranged counterclockwise in this order. The same arrangement is applied to the groups 2 and 3.

That is, when M and K are natural numbers and N is a natural number of 2 or more, and let the m-group n-phase k-th coil in the electric rotating machine 7 with M groups, N phases, and each phase constituted by K coils, be denoted C(m, n, k). In the present application, a natural number is treated as an integer of 1 or more. In this case, the electric rotating machine 7 to be measured satisfies 1≤m≤M, 1≤n≤N, 1≤k≤K, and M=3, N=3, and K=2.

The coils of the electric rotating machine 7 are arranged counterclockwise from the group 1 in ascending order of k, in ascending order of n, and in ascending order of m. Specifically, they are arranged in the following order, starting with C(1, 1, 1), followed by C(1, 1, 2), C(1, 2, 1), C(1, 2, 2), C(1, 3, 1), C(1, 3, 2), C(2, 1, 1), C(2, 1, 2), C(2, 2, 1), C(2, 2, 2), C(2, 3, 1), C(2, 3, 2), C(3, 1, 1), C(3, 1, 2), C(3, 2, 1), C(3, 2, 2), C(3, 3, 1), and C(3, 3, 2).

When the coils of each phase in each group are continuously arranged along the circumferential direction as described above, the amplitude of the voltage waveform of each phase due to the unbalance of the magnetic gap length caused by the static eccentricity and the dynamic eccentricity has a large difference as compared with a case of a discontinuous arrangement. When the difference in the amplitude increases, the L±P-th order harmonic components of each line-to-line voltage used for the estimation of the magnetic gap length also increases, and thus it is possible to further increase the estimation accuracy of the magnetic gap length. As a result, the amount of current applied to each group is adjusted in accordance with the magnetic gap length that varies with time, and it is possible to more efficiently achieve control for suppressing vibration caused by the dynamic eccentricity.

Connection of the electric rotating machine 7 described in FIG. 3 is made as shown in FIG. 4. The coils of each group are formed in independent Y-connection, and the coils of each phase are connected in series. With such a circuit configuration, since the difference in the amplitude of the voltage waveform between the phases becomes larger, the estimation accuracy of the magnetic gap length can be further increased for the same reason as described above. Further, since the coils of each group are formed in the Y-connection and the coils of each phase are connected in series, a circulating current is not generated. Therefore, since there is no influence of an induced voltage caused by the circulating current, the detection accuracy of the line-to-line voltage can be improved.

### <Magnetic Gap Length Estimating Method>

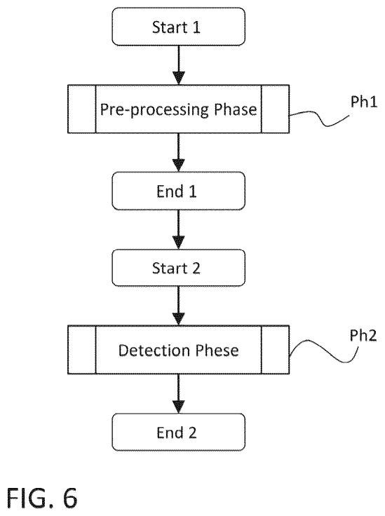

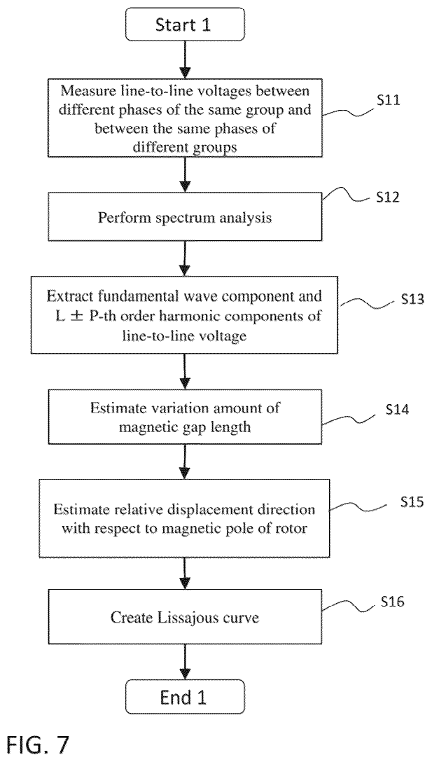

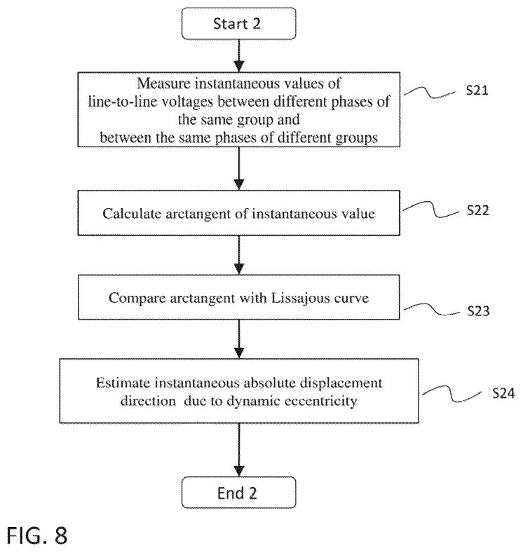

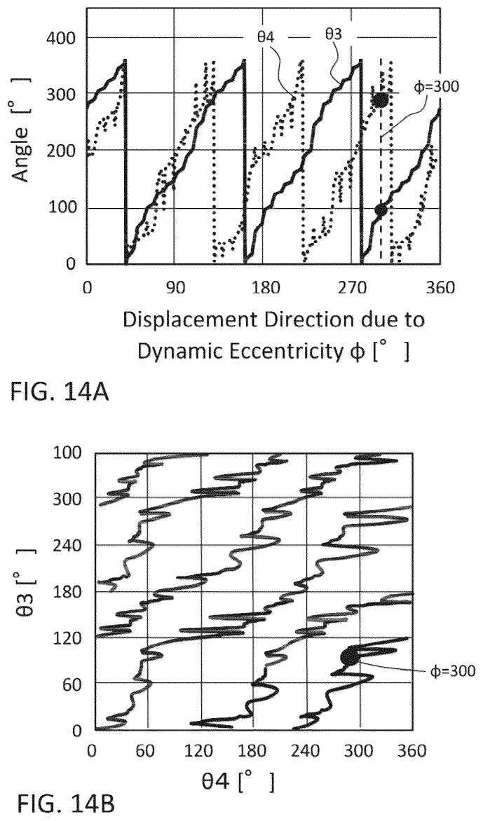

On the premise of the above-described configuration, an operation of the magnetic gap length estimating device 1 according to Embodiment 1, that is, the magnetic gap length estimating method will be described with reference to FIG. 5 to FIG. 14A, and FIG. 14B. FIG. 5 is a schematic view corresponding to FIG. 3, showing a state in which dynamic eccentricity occurs in the electric rotating machine to be measured by the magnetic gap length estimating device, FIG. 6 is a flowchart for describing the entire process in the magnetic gap length estimating method, FIG. 7 is a flowchart for describing a pre-processing phase of two phases constituting the magnetic gap length estimating method, and FIG. 8 is a flowchart for describing the remaining detection phase.

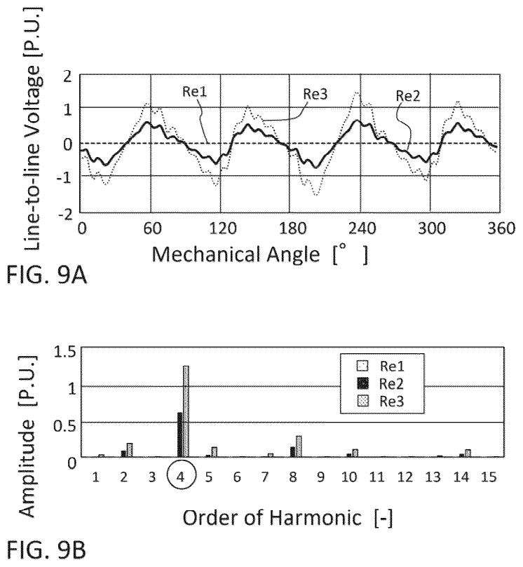

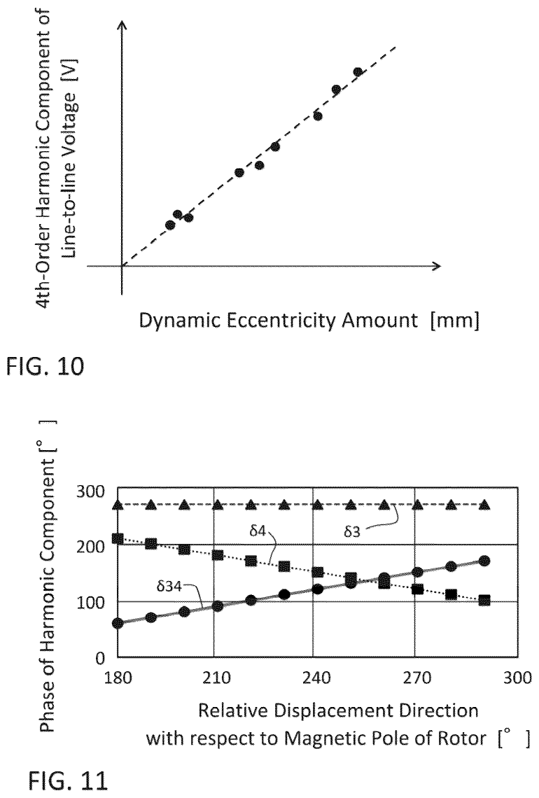

FIG. 9A and FIG. 9B are diagrams for describing an operation of a step of extracting the fundamental wave component and the L±P-th order harmonic components of the line-to-line voltage, FIG. 9A is a waveform diagram of the line-to-line voltage, and FIG. 9B is a diagram in the form of a bar graph showing the amplitude for each order by Fourier transformation. Further, FIG. 10 is a diagram in the form of a line graph showing a relationship between a dynamic eccentricity amount and a harmonic component of the line-to-line voltage for describing an operation of a step of estimating a variation amount of the magnetic gap length. FIG. 11 is a line graph showing a relationship between the third-order component, the fourth-order component, and the difference between the third-order component and the fourth-order component of the line-to-line voltage with respect to a displacement direction for describing an operation of estimating the displacement direction with respect to the magnetic pole position of the rotor.

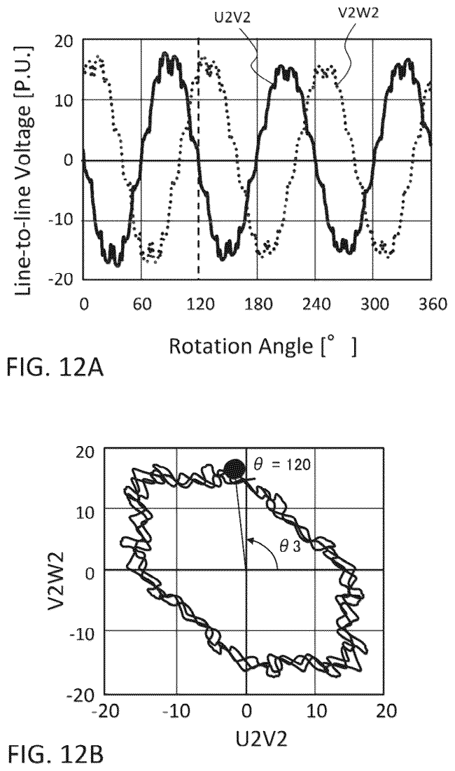

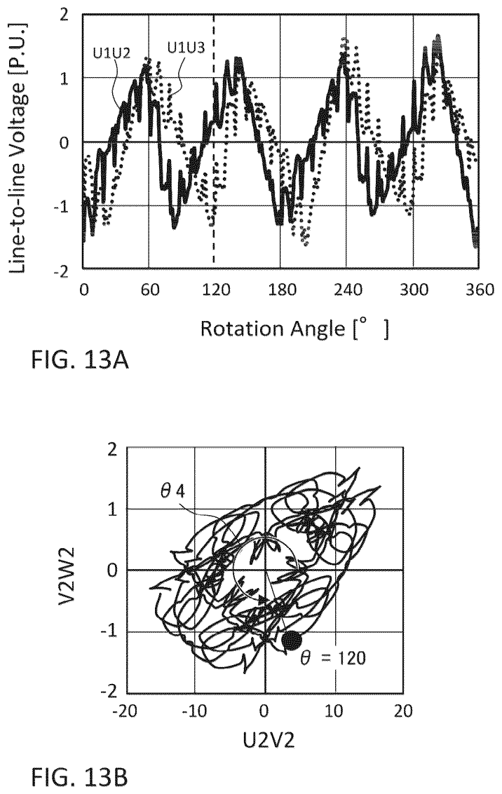

Further, FIG. 12A and FIG. 12B are for describing an operation of a step of creating a Lissajous curve, FIG. 12A is a waveform diagram of the line-to-line voltages between different phases of the same group, and FIG. 12B is a diagram showing Lissajous curves created by arranging the waveforms of FIG. 12A on an X-coordinate and a Y-coordinate at a rotation angle. On the other hand, FIG. 13A and FIG. 13B are also for describing the operation of the step of creating a Lissajous curve, and FIG. 13A is a waveform diagram of the line-to-line voltages between the same phases of different groups, and FIG. 13B is a diagram showing Lissajous curves created by arranging the waveforms of FIG. 13A on an X-coordinate and a Y-coordinate at a rotation angle.

Further, FIG. 14A and FIG. 14B are also for describing the operation of the step of creating a Lissajous curve, and FIG. 14A is a diagram in the form of a line graph showing a relationship between an absolute displacement direction due to the dynamic eccentricity and an angle of the Lissajous curve with respect to a rotational angle, and FIG. 14B is a diagram showing a locus of the angle of the Lissajous curve as the displacing direction changes.

In the electric rotating machine 7, as shown in FIG. 5, it is assumed that a rotation center C2r of the rotor 72 coincides with an inner-diameter center C1s of the stator 71, whereas a shape center C2s of the rotor 72 is shifted to the direction of 180 degrees when the circumferential boundary position between the group 1 and the group 2 is set to 0 degrees. It is also assumed that positions of permanent magnets 72m of six poles are such that the center position (magnetic pole position) of the permanent magnets 72m in the circumferential direction is located at the same 180 degrees position.

In this case, the magnetic gap between the stator 71 and the rotor 72 is not uniform in the circumferential direction, and the length of the magnetic gap varies with time when the rotor 72 rotates. A method of estimating an instantaneous magnetic gap length for the electric rotating machine 7 in such a state will be described. As shown in a flowchart of FIG. 6, the magnetic gap length estimating method according to Embodiment 1 is roughly divided into two phases consisting of a pre-processing phase Ph1 and a detection phase Ph2.

In the pre-processing phase Ph1, information to be stored in the estimation information creation unit 3 is created by rotating the electric rotating machine 7 by at least one rotation. The rotation at this time is in an unloaded state in which no current is supplied to the electric rotating machine 7. As a result, an inspection facility that does not require addition of a current sensor in a manufacturing line can be constructed, and the estimation accuracy of the magnetic gap length can be improved by suppressing the influence of harmonic noise or the like caused by the current load.

In the next detection phase Ph2, a process of estimating an instantaneous magnetic gap length is performed in a driving state in which the electric rotating machine 7 is continuously rotated without the current load or with the current load. The pre-processing phase Ph1, which is the first phase, is completed through Start 1 to End 1, and then the detection phase Ph2, which is the second phase, is completed through Start 2 to End 2.

In a case where an object is to acquire the dynamic eccentricity amount of each sample in the manufacturing line, the estimation may be completed by the pre-processing phase Ph1. In addition, in a case where the pre-processing phase Ph1 is completed and the estimation information is stored in the estimation information creation unit 3, the pre-processing phase Ph1 may be omitted, and only the detection phase Ph2 for estimating the instantaneous magnetic gap length in the normal driving state may be performed from the beginning.

Next, as a detailed operation for each phase, the pre-processing phase will be described first. The pre-processing phase Ph1 executed by the estimation information creation unit 3 includes steps S11 to S16 as shown in the flowchart of FIG. 7. First, the line-to-line induced voltages between different phases of the same group and between the same phases of different groups are acquired at least two locations each (step S11). For example, the voltage acquisition unit 2 of the magnetic gap length estimating device 1 acquires line-to-line voltages between U2 and V2 and between V2 and W2 as the different phases of the same group and line-to-line voltages between U1 and U2 and between U1 and U3 as the same phases of different groups, and the memory unit 31 receives the acquired data and stores the data.

Although the above line-to-line voltages are acquired in the present embodiment, other combinations of phases may be used, such as the acquiring of two locations between U1 and U2 and between V1 and V2 as the same phases of different groups.

Next, in the analysis unit 34, the spectrum analysis unit 341 performs spectrum analysis on the data of the line-to-line voltages stored in the memory unit 31 (step S12). In particular, the spectrum analysis unit 341 applies a fast Fourier transform algorithm to the line-to-line voltages to convert the line-to-line voltages into amplitude and phase information for each of the frequencies. Further, the frequency analysis unit 342 extracts the amplitudes and phases of the fundamental wave component and the L±P-th harmonic components of each of the line-to-line voltages from the amplitude and phase information for each of the frequencies (step S13).

Here, the relationship between the magnetic gap length and the fundamental wave component and the L±P-th harmonic components of a phase voltage and the line-to-line voltage will be described. In the present embodiment, since the measurement target is the electric rotating machine 7 having 6 poles and 36 slots, the number of pole pairs L is 3 (=6/2). Further, the permeance (=inverse of magnetic resistance) of the magnetic gap portion includes a first-order component caused by the dynamic eccentricity in addition to a zero-order component being a main component when one round of the mechanical angle in the magnetic gap portion is set as a reference. Furthermore, considering that the coil interlinkage magnetic flux proportional to the line-to-line induced voltage is calculated by the product of the permeance of the magnetic gap portion and the magnetomotive force of the rotor 72, the order of the main component included in the magnetomotive force of the rotor 72 is the third order equal to the number of pole pairs L of the rotor 72.

From these, according to the sum and product formula of trigonometric functions, the induced voltage waveform of a phase is a waveform in which components of the fourth-order (=3+1) and second-order (=3−1) caused by the variation of the permeance due to the dynamic eccentricity are added to the third-order (=3±0) fundamental wave component of the order equal to the number of pole pairs L per one round of mechanical angle of the rotor 72. In Embodiment 1, since the dynamic eccentricity is assumed, an example in which the order P is set to 1 is shown. However, in addition, in a case where the roundness of the rotor 72 is deteriorated and the rotor 72 is deformed into an elliptical shape, the order P is set to 2 since a second-order component is included in the permeance.

Further, when the permeance per one round of the rotor 72 includes a harmonic component, harmonic components are also generated in the same manner even when the order P is 3 or more, and it is obvious that 3±P-th order components are generated. In addition, although the present embodiment shows an example in which the number of pole pairs L is 3, it is obvious that the L±P-th order component is generated in the electric rotating machine 7 having another number of pole pairs L.

Since the line-to-line voltage waveform is a difference between the phase voltage waveforms of the selected two phases, the phase difference of 120 degrees in the electrical angle exists between the selected phases in the different phases of the same group, and thus the third-order component being the fundamental wave component, and the second-order and fourth-order components caused by the dynamic eccentricity, which are described above, are included without being canceled. On the other hand, since phase values of the selected phases are the same or close values in the same phases of different groups, the third-order component being the fundamental wave component is canceled, and the second-order or fourth-order component caused by the dynamic eccentricity is included in the line-to-line voltage waveform as the main component.

For example, the amplitudes of the line-to-line unloaded induced voltage waveforms of the same phases (U1U3) of different groups and a comparison by each order in the Fourier transformation results when the rotor 72 is rotated by one rotation in the mechanical angle will be described. Here, the results of the line-to-line unloaded induced voltage waveform (voltage in P.U.) when the dynamic eccentricity amount (=dynamic eccentricity ratio) with respect to the magnetic gap length is 0% (Re1: broken line), 20% (Re2: solid line), and 40% (Re3: dotted line) are shown.

As shown in FIG. 9A, it is understood that the line-to-line voltage increases as the dynamic eccentricity increases (Re2, Re3) as compared to the case where there is no dynamic eccentricity (Re1). Further, as shown in FIG. 9B, it is understood that the main component is the fourth-order component and a remarkable increase is observed in proportion to the dynamic eccentricity ratio, and on the other hand, the third-order component being the fundamental wave component is not included.

This will be examined on the basis of the winding structure of the electric rotating machine 7, which is the measurement target of Embodiment 1 described with reference to FIG. 3. In this example, the electrical angle is three times the mechanical angle because of the pole pairs. Therefore, when the circumferential boundary between the group 1 and the group 3 is set to 0 degrees, an electrical center position of the phase coils of each phase in each group is 120, 240, 360, 120, 240, 360, 120, 240, and 360 degrees in the electrical angle in the order of the U, V, and W phases for the groups 1, 2, and 3.

Since the electrical center positions of the U1 phase and the U3 phase coincide with each other at 120 degrees, it is understood that the phase values of the fundamental wave components included in the phase voltages coincide with each other and are canceled by each other in the line-to-line voltage. It is obvious that, as in the present embodiment, when the electrical phase difference in the position in the circumferential direction is 0 degrees in the coils in the same phases of different groups, the fundamental wave components are canceled, and the line-to-line voltage waveform including the component caused by the dynamic eccentricity as the main component is obtained. By making the main component of the line-to-line voltage waveform the component caused by the dynamic eccentricity, the estimation accuracy of the instantaneous magnetic gap length can be improved, and the reason will be described later in detail.

Next, the estimation information calculation unit 35 estimates the magnetic gap length using the fourth-order harmonic component of the line-to-line voltage. Therefore, the estimation information calculation unit 35 estimates an absolute value of a variation amount in the magnetic gap length caused by the dynamic eccentricity (step S14). The dynamic eccentricity amount and the amplitude of the fourth-order harmonic component of the line-to-line voltage have a substantially proportional relationship as shown in FIG. 10. This relationship is stored in the estimation reference storage unit 33 in advance as a database by a theoretical calculation, a simulation, an experiment, or the like. This relationship may be stored in the form of a numerical expression or a numerical value table.

In step S14, the estimation information calculation unit 35 estimates the absolute value of the variation amount of the magnetic gap length caused by the dynamic eccentricity, using the relationship between the dynamic eccentricity amount and the amplitude of the fourth-order harmonic component of the line-to-line voltage stored in the estimation reference storage unit 33.

The estimation information calculation unit 35 estimates a relative displacement direction with respect to the magnetic pole position of the rotor using the phase information of the third-order and fourth-order components of the line-to-line voltage (step S15). Here, changes in the third-order component, the fourth-order component, and the difference between the third-order component and the fourth-order component of the line-to-line voltage when the relative displacement direction with respect to the magnetic pole position of the rotor 72 changes in the range of 180 to 300 degrees with reference to the angles shown in FIG. 5 will be described with reference to FIG. 11. Note that, in FIG. 11, the phase values of the third-order component of the line-to-line voltage between different phases of the same group are denoted by δ3 (▴, broken line), the phase values of the fourth-order component of the line-to-line voltage between the same phases of different groups are denoted by δ4 (▪, dotted line), and the differences between them are denoted by δ34 (=δ3−δ4: ●, solid line).

As shown in FIG. 11, it is understood that the phase values (δ3) of the third-order component, which is the fundamental wave component, do not change with respect to the relative displacement direction with respect to the magnetic pole, whereas the phase values (δ4) of the fourth-order component changes in a linear function manner. That is, the phase values (δ3) of the third-order component included in the line-to-line voltage waveform between different phases of the same group and the phase values (δ4) of the fourth-order component included in the line-to-line voltage waveform between the same phases of different groups are extracted, and the differences (δ34) between them are calculated.

On the other hand, information on the relationship between δ3, δ4, and δ34 with respect to an assumed displacement direction is stored in the estimation reference storage unit 33 as a database by a theoretical calculation, a simulation, an experiment, or the like. Thus, by comparing the obtained result with the stored information, the relative displacement direction with respect to the magnetic pole position of the rotor 72 can be estimated. That is, when information on the magnetic pole position of the rotor 72 is obtained, the absolute displacement direction caused by the dynamic eccentricity can be estimated.

To formulate this, if a rotation angle when the magnetic pole center is set as a 0 degree reference is set as θ and a relative displacement direction with respect to the magnetic pole position of the rotor 72 calculated from the above-described relationship is set as α, an absolute displacement direction φ of the magnetic gap length caused by the dynamic eccentricity can be calculated by Expression (1).

$$Φ = θ + α \qquad ( 1 )$$

Note that, in the present embodiment, the absolute displacement direction of the magnetic gap length caused by the dynamic eccentricity is set to correspond to the position where the magnetic gap is the smallest.

Subsequently, using the line-to-line voltage waveforms between different phases of the same group and between the same phases of different groups acquired in step S11, respective Lissajous curves are created (step S16). As shown in FIG. 12A and FIG. 12B, and FIG. 13A and FIG. 13B, it is possible to draw Lissajous curves each of which rotates three times and four times for every rotation angle of 360 degrees. Note that, U2V2 (solid line) and V2W2 (dotted line) as the line-to-line voltage waveforms between the different phases of the same group are shown in FIG. 12A, and U1U2 (solid line) and U1U3 (dotted line) as the line-to-line voltage waveforms between the same phases of different groups are shown in FIG. 13A.

When angles θ3 and θ4 in the Lissajous curve with respect to the rotation angle θ are defined, it is understood that θ3 changes in three cycles and θ4 changes in four cycles while the rotation angle θ changes from 0 to 360 degrees. Here, a relationship in which θ3 and θ4 change in accordance with the absolute displacement direction φ caused by the dynamic eccentricity, and a locus with θ3 on the vertical axis and θ4 on the horizontal axis when φ changes from 0 to 360 degrees will be examined using FIG. 14A and FIG. 14B. Note that, in FIG. 14A, θ3 is indicated by a solid line, and θ4 is indicated by a dotted line.

As shown in FIG. 14B, since there is no overlap in the locus, it is understood that θ3 and θ4 are uniquely determined with respect to the absolute displacement direction φ caused by the dynamic eccentricity. That is, by extracting θ3 and θ4 from the obtained line-to-line voltage waveforms, the absolute displacement direction φ caused by the dynamic eccentricity can be uniquely determined.

Since θ3 and θ4 can be calculated from the instantaneous values of the line-to-line voltage waveforms, it is possible to estimate the absolute displacement direction φ caused by the instantaneous dynamic eccentricity by using the above-described relationship of the locus. This will be described in detail with reference to the flowchart of the detection phase shown in FIG. 8.

That is, instantaneous values of the line-to-line voltages at two locations each between different phases of the same group and between the same phases of different groups during continuous operation are measured (acquired) (step S21). The instantaneous values of the two locations of the line-to-line voltages between different phases of the same group are each arranged on the X-coordinate and the Y-coordinate, and the arctangent thereof is calculated as θ3, and the instantaneous values of the two locations of the line-to-line voltages between the same phases of different groups are each arranged on the X-coordinate and the Y-coordinate, and the arctangent thereof is calculated as θ4 (step S22).

The calculated θ3 and θ4 are compared with the relationship of the Lissajous curve shown in FIG. 14B, for example, created in step S16 of the pre-processing phase Ph1 (step S23). As described above, since θ3 and θ4 are uniquely determined with respect to the absolute displacement direction φ caused by the dynamic eccentricity, the instantaneous absolute displacement direction φ caused by the dynamic eccentricity can be estimated from the comparison result (step S24).

Note that, in FIG. 12B, FIG. 13B, and FIG. 14B, an example in which the rotation angle θ of the rotor 72 is 120 degrees is shown. In the example of the present embodiment, the relative displacement direction a with respect to the magnetic pole of the rotor 72 is 180 degrees, and the instant absolute displacement direction φ caused by the dynamic eccentricity is 360 degrees (=120 degrees+180 degrees).

That is, by acquiring the dynamic eccentricity amount estimated in the pre-processing phase Ph1 and the instantaneous absolute displacement direction caused by the dynamic eccentricity estimated in the detection phase Ph2, the instantaneous magnetic gap length can be visualized and monitored.

As described above, the magnetic gap length estimating device 1 of Embodiment 1 includes the voltage acquisition unit 2 that acquires the line-to-line voltages, the estimation information creation unit 3 that creates information for estimating the instantaneous magnetic gap length of the electric rotating machine 7, and the instantaneous gap length estimation unit 4 that estimates the instantaneous magnetic gap length by comparing the information with the instantaneous line-to-line voltages.

The estimation information creating unit 3 includes the spectrum analysis unit 341 that converts the line-to-line voltage into an amplitude and a phase for each frequency, the frequency analysis unit 342 that extracts the amplitude and phase of the fundamental wave component and the L±P-th harmonic components of the line-to-line voltage from the amplitude and the phase for each frequency, and the estimation information calculation unit 35 that calculates the estimation information for estimating the magnetic gap length of the electric rotating machine from the amplitude and phase of the fundamental wave component and the L±P-th harmonic components of the line-to-line voltage. Therefore, the magnetic gap length estimating device 1 of Embodiment 1 does not require addition of equipment such as a current sensor and a current load, and does not require voltage measurement at the neutral point of the connection limes.

In Embodiment 1 described above, an example in which the fourth-order component is focused on as the feature amount of the dynamic eccentricity has been described. However, the second-order component may be the main component depending on the structures of the rotor 72 and the stator 71, and a component of another order may be focused on. Further, with respect to the number of pole pairs, in the dynamic eccentricity in the case of the structure of L pole pairs instead of three pole pairs, it is obvious that any component of L±1 order becomes the main component, and attention should be paid to the L±1 order component that is to be the main component depending on the structure.

In addition, as described above, even in a case where the permeance variation is of the second or higher order due to a factor other than the dynamic eccentricity, the instantaneous magnetic gap length can be estimated by the same method. Therefore, attention should be paid to the L±P-th order component which is to be the main component depending on the structure. Further, in the present embodiment, an example of the dynamic eccentricity in which the shape center is displaced in the direction of the magnetic pole center of the rotor 72 with reference to the rotation center has been described. The magnetic gap length estimating device 1 of the present embodiment can obtain the same effect even when the dynamic eccentricity occurs in other directions.

In addition, FIG. 1 shows an example in which the voltage acquisition unit 2 of the magnetic gap length estimating device 1 is connected to each of the connection lines 9 (nine lines) connecting the three-group three-phase winding and the electric rotating machine 7. However, the magnetic gap length estimating device 1 according to Embodiment 1 can estimate the instantaneous magnetic gap length by acquiring a line-to-line voltage of at least one location in the same phases and in the different groups (the same phases of different groups) together with a line-to-line voltage between the same phases of the same group to create a Lissajous curve. That is, it is not necessary to connect all of the nine connection lines 9 to the voltage acquisition unit 2 as long as the minimum number of line-to-line voltage waveforms with which a Lissajous curve can be created can be acquired.

### Variation

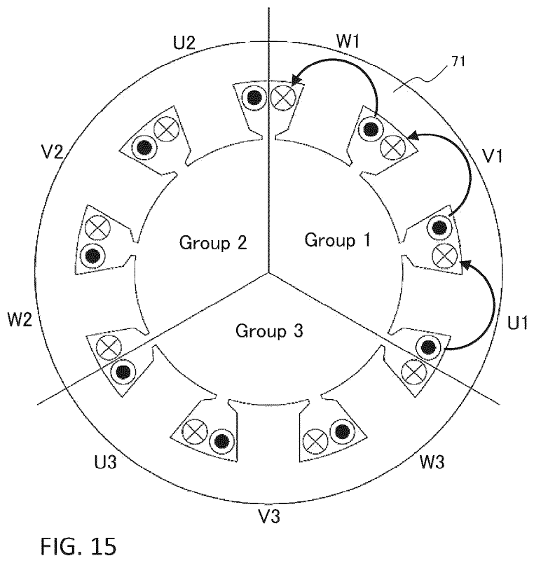

In the present variation, an example will be described in which an electric rotating machine having a rotor with a different number of slots is a measurement target instead of the electric rotating machine having the rotor with the 6-pole 36-slot configuration described in FIG. 3. FIG. 15 is a plan view perpendicular to the axis, showing a configuration of a stator of the electric rotating machine to be measured by a magnetic gap length estimating device according to the present variation. In FIG. 15, as in FIG. 3, the direction of the current flowing through each coil is indicated by two types of symbols, and the rotor is omitted in the figure.

As shown in FIG. 15, the electric rotating machine 7 to be measured by the magnetic gap length estimating device 1 according to the present variation has a configuration of 6 poles and 9 slots in which a coil is wound around one tooth by concentrated winding. In the electric rotating machine 7, when an m-group n-phase k-th coil is denoted by C (m, n, k), 1≤m≤M, 1≤n≤N, 1≤k≤K, M=3, N=3, and K=1.

The coils of the electric rotating machine 7 are arranged counterclockwise in ascending order of k, in ascending order of n, and in ascending order of m from the group 1. Specifically, they are arranged in the order of C(1, 1, 1), C(1, 2, 1), C(1, 3, 1), C(2, 1, 1), C(2, 2, 1), C(2, 3, 1), C(3, 1, 1), C(3, 2, 1), and C(3, 3, 1).

Even in such a concentrated winding electric rotating machine 7, since the coils of each phase in each group are continuously arranged in the circumferential direction, the difference in the amplitude of the voltage waveform between phases due to an unbalance of the magnetic gap length caused by the eccentricity increases. Therefore, since the second-order or fourth-order harmonic component included in the line-to-line voltage also increases, it is possible to further increase the estimation accuracy of the magnetic gap length.

Note that, in the magnetic gap length estimating device 1 according to Embodiment 1 or the variation example thereof, the line-to-line voltage between coil phases belonging to different groups are measured. The coils of each group are formed in independent Y-connection. For this reason, there is a possibility that an offset component of the potential difference caused by the fact that the coils of each group are electrically independent is included in the line-to-line voltage between the two phases each of which belongs to a different group. To remove this offset component, the neutral point of the Y-shaped connection in the coils of each group may be electrically connected to each other.

### Embodiment 2

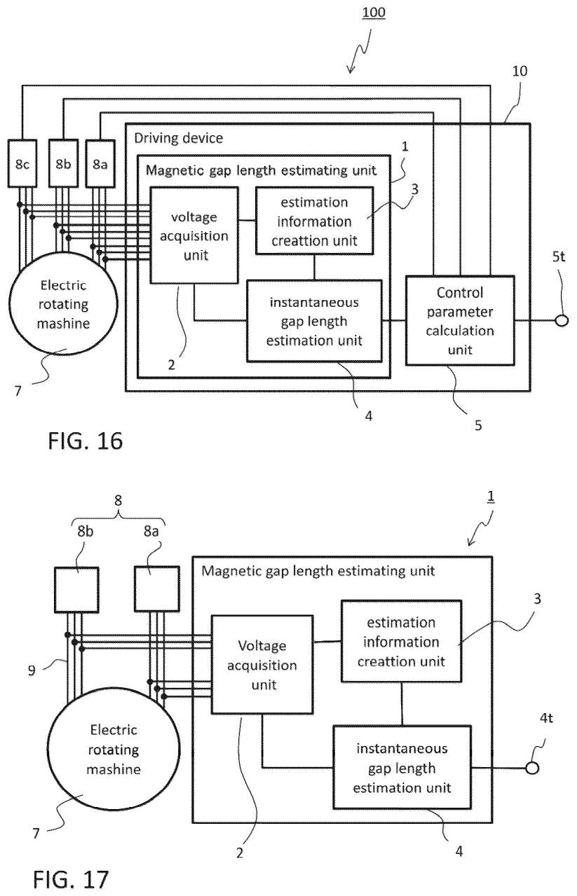

In Embodiment 1, the magnetic gap length estimating device that estimates the magnetic gap length of the electric rotating machine has been described. In Embodiment 2, a driving device for the electric rotating machine including the magnetic gap length estimating device described in Embodiment 1, and an electric rotating machine system will be described. FIG. 16 is a block diagram for describing a configuration of the driving device for the electric rotating machine and the electric rotating machine system according to Embodiment 2. Since the configuration and the operation of the magnetic gap length estimating device itself are the same as those in Embodiment 1, the description of the same parts will be omitted.

As shown in FIG. 16, a driving device 10 for the electric rotating machine according to Embodiment 2 includes the magnetic gap length estimating device 1 described in Embodiment 1 and a control parameter calculation unit 5 that receives an output from the instantaneous gap length estimation unit 4 and transmits a control parameter to the inverter 8. Further, an electric rotating machine system 100 is configured with the electric rotating machine 7, the inverter 8, and the driving device 10 of the electric rotating machine. The control parameter calculation unit 5 transmits to each of the three inverters 8a to 8c control parameters for adjusting a current input value to each group of the electric rotating machine 7 on the basis of the magnetic gap length estimated by the magnetic gap length estimating device 1.

That is, the magnetic gap length estimating device 1 in the driving device 10 has a relationship such that the external output terminal 4t of the instantaneous gap length estimation unit 4 described in FIG. 1 is connected to the control parameter calculation unit 5. On the other hand, the control parameter calculation unit 5 has an external output terminal 5t, and the control parameters can be visualized by, for example, connecting an external monitor to the external output terminal St. Of course, the information on the state of the magnetic gap obtained from the instantaneous gap length estimation unit 4 may also be outputted from the external output terminals 5t and visualized.

On the premise of the above configuration, a control operation of the driving device 10 will be described. For example, it is assumed that the electric rotating machine 7 has dynamic eccentricity in which the shape center is displaced in the direction of the magnetic pole center of the rotor 72 with reference to the rotation center as described in Embodiment 1. In this situation, it is assumed that the detection phase Ph2 in the unloaded state is also completed using estimation information obtained in the pre-processing phase Ph1 described in Embodiment 1 in which the electric rotating machine 7 is rotated in the unloaded state. That is, it is assumed that a variation characteristic of the magnetic gap length corresponding to the rotational position of the rotor 72 is obtained.

In contrast to this state, when the electric rotating machine 7 is rotated with a load applied, the waveform to be obtained will be different from that in the unloaded state, but the rotational position can be grasped through the output state of the inverter 8 for the electric rotating machine 7 with multiple groups and multiple phases. Therefore, when the instantaneous rotor position is in a situation as shown in FIG. 5, the control parameter calculation unit 5 transmits a control parameter to each inverter 8 so as to adjust the current input value as follows on the basis of the grasped rotational position.

In the situation shown in FIG. 5, the magnetic gap length of the group 3 is smaller than the magnetic gap lengths of the group 1 and the group 2 as in the case of the unloaded state. Since such a situation occurs in correspondence to the rotational position, the current input value to the coils belonging to the group 3 is set to be smaller than the current input values to the coils belonging to the groups 1 and 2 at the instantaneous time (rotational position). When time further elapses, for a situation (rotational position) corresponding to a different group having a position at which the magnetic gap length becomes smaller, the current value for the group is set to be smaller than those of the other groups.

In this way, by the estimation information obtained in the pre-processing phase Ph1 and the inspection phase Ph2 in the unloaded state using the estimation information, the eccentric state corresponding to the rotational position of the rotor 71 is grasped Then, since the rotational position at the time of actually driving the electric rotating machine 7 can be grasped by the operation state of the invertor 8, the setting of the current value of each group is changed in accordance with the magnetic gap length changing with the rotational position. By performing such control, it is possible to implement the electric rotating machine system 100 capable of reducing vibration and noise caused by the dynamic eccentricity.

Note that, also in Embodiment 2, an example is shown in which the voltage acquisition unit 2 of the magnetic gap length estimating device 1 is connected to each of the connection lines 9 (nine lines) connecting the three-group three-phase winding and the electric rotating machine 7. However, the magnetic gap length estimating device 1 can estimate the instantaneous magnetic gap length by acquiring a line-to-line voltage of at least one location in the same phases of different groups together with a line-to-line voltage between different phases of the same group to create a Lissajous curve as in Embodiment 1 in which the magnetic gap length estimating device 1 is used alone. That is, when the minimum number of line-to-line voltage waveforms with which a Lissajous curve can be created can be acquired without connecting all of the nine connection lines 9 to the voltage acquisition unit 2, the control parameters can be calculated by estimating the direction in which the magnetic gap length is displaced.

### Embodiment 3

In Embodiment 1 and Embodiment 2, the case where the electric rotating machine driven by the three-group three-phase inverter is the measurement target has been described. In Embodiment 3 and Embodiment 4, a case where an electric rotating machine driven by a two-group three-phase inverter is a measurement target will be described.

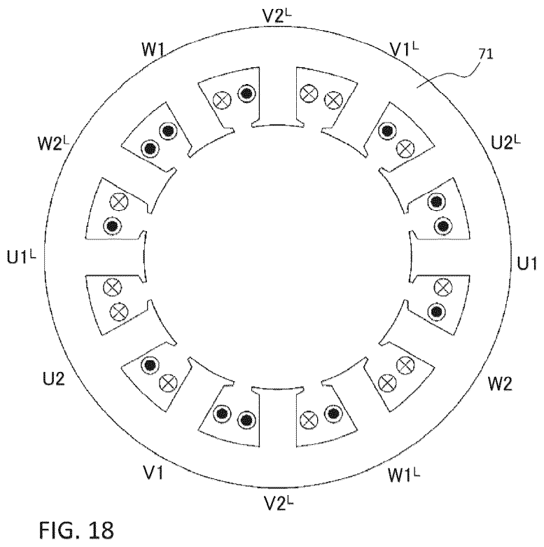

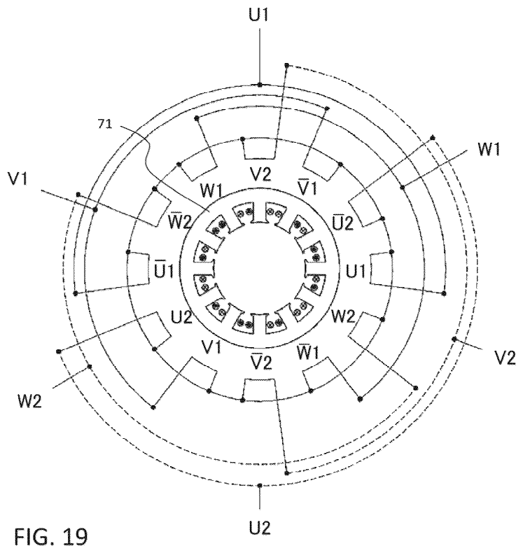

FIG. 17 and FIG. 18 are diagrams for describing a configuration and an operation of a magnetic gap length estimating device according to Embodiment 3, FIG. 17 is a block diagram including an electric rotating machine to be measured and an inverter for describing the configuration of the magnetic gap length estimating device, FIG. 18 is a plan view perpendicular to an axis, showing a configuration of a stator of the electric rotating machine to be measured by the magnetic gap length estimating device, and FIG. 19 is a connection diagram of the stator of the electric rotating machine, corresponding to FIG. 17. Note that FIG. 2 and FIG. 6 to FIG. 8 used in Embodiment 1 are also referred to, and the description of the same parts will be omitted.

As shown in FIG. 17, the magnetic gap length estimating device 1 according to Embodiment 3 is intended for measurement of the electric rotating machine 7 driven by the two-group three-phase inverter 8. The magnetic gap length estimating device 1 according to Embodiment 3 also includes the voltage acquisition unit 2, the estimation information creation unit 3, and the instantaneous gap length estimation unit 4, as in Embodiment 1. However, the voltage acquisition unit 2 acquires voltages of six connection lines 9 connecting the two inverters 8a and 8b and the electric rotating machine 7. Further, the operation of the magnetic gap length estimating device 1 according to Embodiment 3, that is, the magnetic gap length estimating method according to Embodiment 3, is partially different from the operation described in Embodiment 1.

As shown in FIG. 18, the electric rotating machine 7 to be measured by the magnetic gap length estimating device 1 according to Embodiment 3 has a 10-pole 12-slot configuration (the number of pole pairs: L=5) in which a two-group three-phase inverter drive is assumed. That is, for estimating the magnetic gap length in Embodiment 3, the fifth-order component is used as the fundamental wave component, and the fourth-order or sixth-order harmonic component is used as the feature amount when the dynamic eccentricity is assumed. The others in the method for estimating the magnetic gap length are the same as those in Embodiment 1.

The coils of the stator 71 are configured into a group 1 and a group 2. In FIG. 18, the direction of the current flowing through each coil is indicated by two kinds of symbols as in FIG. 3. The stator 71 of the electric rotating machine 7 has a concentrated winding structure in which one coil is wound around one stator tooth. Both of the group 1 and the group 2 are composed of three phases of U, V, and W phases, and each phase is constituted by two coils. For example, the U-phase coil includes two coils U1 and U1^{L} in which the directions of currents are different from each other, and the symbol “L” indicates that the winding direction of the concentrated winding coil is an opposite direction. The coils of the electric rotating machine 7 are arranged counterclockwise in the order of U1, U2^{L}, V1^{L}, V2, W1, W2^{L}, U1^{L}, U2, V1, V2^{L}, W1^{L}, and W2.

As shown in FIG. 19, the coils of the group 1 and the group 2 are configured in a Y-connection sharing the neutral point, and the coils of each phase are connected in parallel. The group 1 and the group 2 have a phase difference of 30 degrees in the electrical angle. With such a circuit configuration, it is possible to obtain the effect of the magnetic gap length estimating device 1 of the present application while minimizing the number of inverters to be used, and it is possible to suppress the cost for implementing the system. In addition, there is a phase difference between the groups, so that a fundamental wave component is included in the line-to-line voltage waveform between the same phases of different groups, and thus the variation of the Lissajous curve increases and the detection accuracy of the dynamic eccentricity decreases. However, it is also possible to suppress the torque pulsation generated in the electric rotating machine 7.

Also in Embodiment 3, an example is shown in which the voltage acquisition unit 2 of the magnetic gap length estimating device 1 is connected to each of the connection lines 9 (six lines) connecting the two-group three-phase winding and the inverter 8. However, when the minimum number of line-to-line voltage waveforms with which a Lissajous curve can be created can be acquired without connecting all of the six connection lines 9 to the voltage acquisition unit 2, the direction in which the magnetic gap length is displaced can be estimated.

Further, in Embodiment 3, the case where the neutral point is shared by the group 1 and the group 2 has been described. However, even when the neutral point is independent in each group, the same effect can be obtained although the disturbance due to mixing of an offset component increases. In Embodiment 3, the case where the coils of each phase are connected in parallel has been described. However, by changing the coils of each phase to be connected in series, the sensitivity to the difference in the magnetic gap length can be further improved. In Embodiment 3, the case where the group 1 and the group 2 have a phase difference of 30 degrees in the electrical angle has been described, but the connection may be such that the phase difference is 0 degrees.

### Embodiment 4

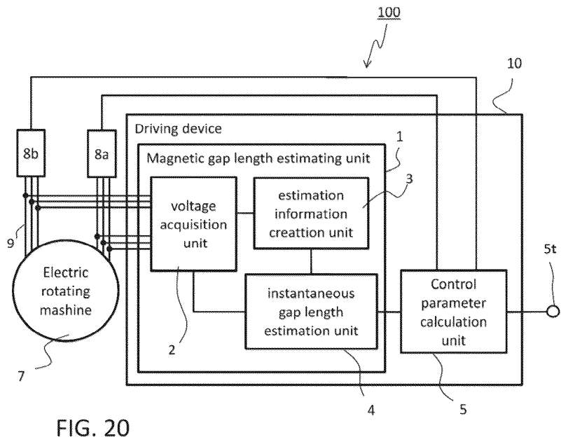

In Embodiment 4, similarly to the relationship between Embodiment 1 and Embodiment 2, a driving device of an electric rotating machine including the magnetic gap length estimating device described in Embodiment 3, and an electric rotating machine system will be described. FIG. 20 is a block diagram for describing a configuration of the driving device for the electric rotating machine and the electric rotating machine system according to Embodiment 4. Since the configuration and the operation of the magnetic gap length estimating device itself are the same as those of Embodiment 3, the description of the same parts will be omitted.

As shown in FIG. 20, the driving device 10 for the electric rotating machine according to Embodiment 4 includes the magnetic gap length estimating device 1 described in Embodiment 3 and the control parameter calculation unit 5 that receives an output from the instantaneous gap length estimation unit 4 and transmits the control parameters to the inverter 8. The electric rotating machine 7, the inverter 8, and the driving device 10 constitute the electric rotating machine system 100. The control parameter calculation unit 5 transmits to each of the two inverters 8a and 8b a control parameter for adjusting a current input value to each group of the electric rotating machine 7 on the basis of the magnetic gap length estimated by the magnetic gap length estimating device 1.

That is, also in the driving device 10 according to Embodiment 4, the magnetic gap length estimating device 1 has the relationship such that the external output terminal 4t shown in FIG. 17 is connected to the control parameter calculation unit 5. On the other hand, the control parameter calculation unit 5 has the external output terminal 5t, and the control parameters can be visualized by, for example, connecting an external monitor to the external output terminal St. Of course, the information on the state of the magnetic gap obtained from the magnetic gap length estimating device 1 may also be outputted from the external output terminals 5t and visualized.

With the above configuration and as in the description of Embodiment 2, the detection phase Ph2 is performed on the basis of the estimation information obtained in the pre-processing phase Ph1, and the variation characteristic of the magnetic gap length corresponding to the rotational position of the rotor 72 is obtained. That is, a control operation of the driving device 10 will be described on the premise that the variation characteristic of the magnetic gap length corresponding to the rotational position of the rotor 72 is obtained.

In the driving device 10 according to Embodiment 4, for example, harmonic components of the electromagnetic force are generated in the magnetic gap portion by making the current input values to the group 1 and the group 2 be different and varied in accordance with the instantaneous rotor position. Thus, it is possible to suppress the harmonic components of the electromagnetic force caused by the permeance variation due to the dynamic eccentricity or the like that varies with time. By performing the control in this way, it is possible to implement the electric rotating machine system 100 capable of reducing vibration and noise caused by variation factors such as the dynamic eccentricity or the like that varies with time.

Note that, also in Embodiment 4, an example is shown in which the voltage acquisition unit 2 of the magnetic gap length estimating device 1 is connected to each of the connection lines 9 (six lines) connecting the two-group three-phase winding and the electric rotating machine 7. However, the magnetic gap length estimating device 1 can estimate the instantaneous magnetic gap length by acquiring a line-to-line voltage of at least one location in the same phases of different groups together with a line-to-line voltage between different phases of the same group to create a Lissajous curve as in Embodiment 3 in which the magnetic gap length estimating device 1 is used alone. That is, when the minimum number of line-to-line voltage waveforms with which a Lissajous curve can be created can be acquired without connecting all of the six connection lines 9 to the voltage acquisition unit 2, the control parameters can be calculated by estimating the direction in which the magnetic gap length is displaced.

### Embodiment 5

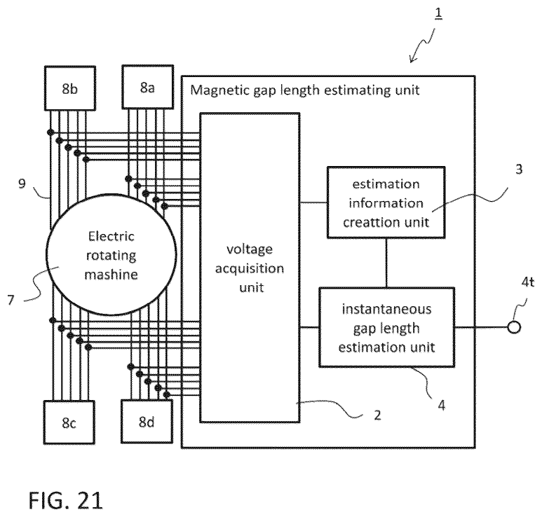

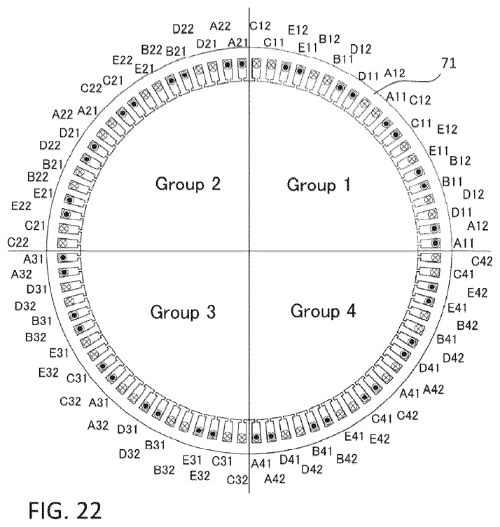

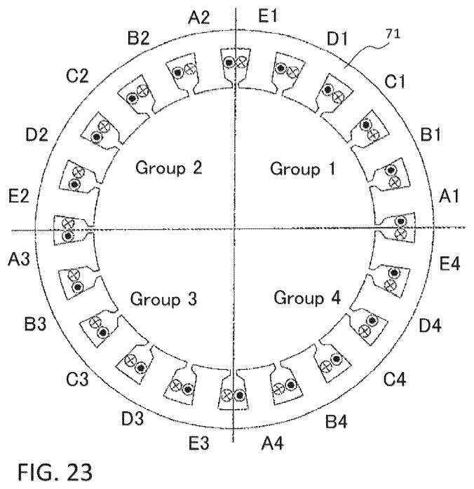

In Embodiment 5 and Embodiment 6, a case where an electric rotating machine driven by a four-group five-phase inverter is a measurement target will be described. FIG. 21 to FIG. 23 are diagrams for describing a configuration and an operation of a magnetic gap length estimating device according to Embodiment 5, FIG. 21 is a block diagram including the electric rotating machine to be measured and an inverter for describing the configuration of the magnetic gap length estimating device, FIG. 22 is a plan view perpendicular to an axis, showing a configuration of a stator of the electric rotating machine to be measured by the magnetic gap length estimating device, and FIG. 23 is a plan view perpendicular to the axis of the stator showing a configuration of another electric rotating machine to be measured by the magnetic gap length estimating device. Note that, also in Embodiment 5, FIG. 2 and FIG. 6 to FIG. 8 used in Embodiment 1 are referred to, and the description of the same parts will be omitted.

As shown in FIG. 21, the magnetic gap length estimating device 1 according to Embodiment 5 is intended for measurement of the electric rotating machine 7 driven by a four-group five-phase inverter 8. The magnetic gap length estimating device 1 according to Embodiment 5 also includes the voltage acquisition unit 2, the estimation information creation unit 3, and the instantaneous gap length estimation unit 4, as in Embodiment 1. However, the voltage acquisition unit 2 acquires the line-to-line voltages in twenty connection lines 9 connecting four inverters 8a to 8d and the electric rotating machine 7. Further, an operation of the magnetic gap length estimating device 1 according to Embodiment 5, that is, a magnetic gap length estimating method according to Embodiment 5, is partially different from the operation described in Embodiment 1.

As shown in FIG. 22, the electric rotating machine 7 to be measured by the magnetic gap length estimating device 1 according to Embodiment 5 has an 8-pole 80-slot configuration (the number of pole pairs: L=4) in which four-group five-phase inverter drive is assumed. That is, for estimating the magnetic gap length in Embodiment 5, the fourth-order component is used as the fundamental wave component, and the third-order or fifth-order harmonic component is used as the feature amount when the dynamic eccentricity is assumed. The others in the method for estimating the magnetic gap length are the same as those in Embodiment 1.

The coils of the stator 71 are configured with groups 1 to 4, and each of the groups is arranged with a phase difference of 90 degrees (=360/4) to each other in the mechanical angle. In addition, in FIG. 22, the direction of the current flowing through each coil is indicated by two kinds of symbols as in FIG. 3. The stator 71 of the electric rotating machine 7 has a distributed winding structure in which a coil is arranged across a plurality of the slots. The coils of each group are composed of five phases of A, B, C, D, and E phases, and each phase is constituted by two coils.

For example, the A phase of the group 1 has two coils A11 and A12. The coils of each group are continuously wound in the circumferential direction in the order of A, D, B, E, and C phase. For example, the coils of the group 1 are arranged counterclockwise in the order of A11, A12, D11, D12, B11, B12, E11, E12, C11, and C12.

That is, when an m-group n-phase k-th coil in the electric rotating machine with M groups, N phases, and each phase constituted by K coils is denoted by C (m, n, k), for the electric rotating machine 7 shown in FIG. 22 1≤m≤M, 1≤n≤N, and 1≤k≤K, and M=4, N=5, and K=2 are satisfied.

The coils of this rotating armature 7 are arranged counterclockwise in ascending order of k, ascending order of n, and ascending order of m. Specifically, they are arranged in the order of C(1, 1, 1), C(1, 1, 2), C(1, 2, 1), C(1, 2, 2), C(1, 3, 1), C(1, 3, 2), C(1, 4, 1), C(1, 4, 2), C(1, 5, 1), C(1, 5, 2), C(2, 1, 1), C(2, 1, 2), C(2, 2, 1), C(2, 2, 2), C(2, 3, 1), C(2, 3, 2), C(2, 4, 1), C(2, 4, 2), C(2, 5, 1), C(2, 5, 2), C(3, 1, 1), C(3, 1, 2), C(3, 2, 1), C(3, 2, 2), C(3, 3, 1), C(3, 3, 2), C(3, 4, 1), C(3, 4, 2), C(3, 5, 1), C(3, 5, 2), C(4, 1, 1), C(4, 1, 2), C(4, 2, 1), C(4, 2, 2), C(4, 3, 1), C(4, 3, 2), C(4, 4, 1), C(4, 4, 2), C(4, 5, 1), and C(4, 5, 2).

By continuously arranging the coils of each phase in each group in the circumferential direction in this way, the difference in the amplitude of the voltage waveform between phases due to the imbalance in the magnetic gap length increases. When the difference in the amplitude of the voltage waveform between phases increases, the L±P-th order harmonic components of each line-to-line voltage used for the estimation of the magnetic gap length also increases, and thus it is possible to further increase the estimation accuracy of the magnetic gap length.

### <Another Measurement Target>

In addition, without being limited to the above example, a case of another electric rotating machine 7 having an 8-pole 20-slot configuration shown in FIG. 23, in which 4-group 5-phase inverter drive is assumed, will be described as a measurement target. The coils of the stator 71 are configured with groups 1 to 4, and each of the groups is arranged with a phase difference of 90 degrees (=36014) to each other in the mechanical angle. In FIG. 23, the direction of the current flowing through each coil is indicated by two kinds of symbols. The stator 71 of the electric rotating machine 7 has a distributed winding structure in which a coil is arranged across a plurality of the slots. The coils of each group are composed of five phases of A, B, C, D, and E phases. The coils of each group are continuously wound in the circumferential direction in the order of A, B, C, D, and E phase.

That is, when an m-group n-phase k-th coil in the electric rotating machine with M groups, N phases, and each phase constituted by K coils is denoted by C (m, n, k), for the electric rotating machine 7 shown in FIG. 23, 1≤m≤M, 1≤n≤N, and 1≤k≤K, and M=4, N=5, and K=1 are satisfied. The coils of the electric rotating machine 7 are arranged counterclockwise in ascending order of k, in ascending order of n, and in ascending order of m. Specifically, they are arranged in the order of C(1, 1, 1), C(1, 2, 1), C(1, 3, 1), C(3, 4, 1), C(3, 5, 1), C(2, 1, 1), C(2, 2, 1), C(2, 3, 1), C(2, 4, 1), C(2, 5, 1), C(3, 1, 1), C(3, 2, 1), C(3, 3, 1), C(3, 4, 1), C(3, 5, 1), C(4, 1, 1), C(4, 2, 1), C(4, 3, 1), C(4, 4, 1), and C(4, 5, 1).

By continuously arranging the coils of each phase in each group along the circumferential direction in this way, the difference in the amplitude of the voltage waveform between phases due to the imbalance in the magnetic gap length increases. When the difference in the amplitude of the voltage waveform between phases increases, the L±P-th order harmonic components of each line-to-line voltage used for the estimation of the magnetic gap length also increases, and thus it is possible to further increase the estimation accuracy of the magnetic gap length.

Note that, also in Embodiment 5, the voltage acquisition unit 2 of the magnetic gap length estimating device 1 is connected to each of the twenty connection lines 9 connecting the four-group five-phase winding and the electric rotating machine 7, but this is not a limitation. That is, when the minimum number of line-to-line voltage waveforms with which a Lissajous curve can be created can be acquired without connecting all of the twenty connection lines 9 to the voltage acquisition unit 2, the direction in which the magnetic gap length is displaced can be estimated.

### Embodiment 6

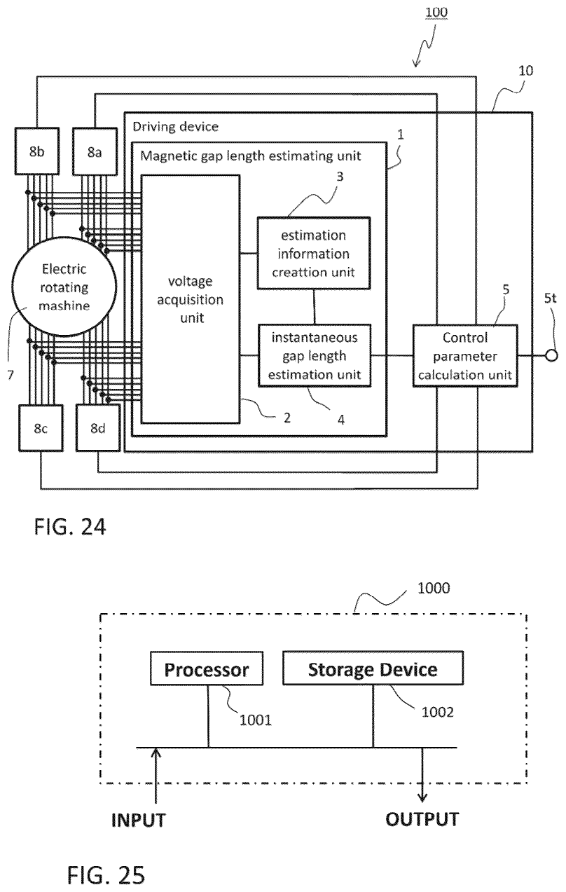

In Embodiment 6, similarly to the relationship between Embodiment 1 and Embodiment 2 and the relationship between Embodiment 3 and Embodiment 4, a driving device for an electric rotating machine including the magnetic gap length estimating device described in Embodiment 5, and an electric rotating machine system will be described. FIG. 24 is a block diagram for describing a configuration of the driving device for the electric rotating machine and the electric rotating machine system according to Embodiment 6. Since the configuration and the operation of the magnetic gap length estimating device itself are the same as those in Embodiment 5, the description of the same parts will be omitted.

As shown in FIG. 24, the driving device 10 for the electric rotating machine according to Embodiment 6 includes the magnetic gap length estimating device 1 described in Embodiment 5 and the control parameter calculation unit 5 that receives an output from the instantaneous gap length estimation unit 4 and transmits control parameters to the inverter 8. The electric rotating machine 7, the inverter 8, and the driving device 10 constitute the electric rotating machine system 100. The control parameter calculation unit 5 transmits to each of the four inverters 8a to 8d a control parameter for adjusting a current input value to each group of the electric rotating machine 7 on the basis of the magnetic gap length estimated by the magnetic gap length estimating device 1.

That is, also in the driving device 10 according to Embodiment 6, the magnetic gap length estimating device 1 has the relationship such that the external output terminal 4t shown in FIG. 21 is connected to the control parameter calculation unit 5. On the other hand, the control parameter calculation unit 5 has the external output terminal 5t, and the control parameters can be visualized by, for example, connecting an external monitor to the external output terminal St. Of course, the information on the state of the magnetic gap obtained from the magnetic gap length estimating device 1 may also be outputted from the external output terminal 5t and visualized.

With the above configuration and as in the description of Embodiment 2, the detection phase Ph2 is performed on the basis of the estimation information obtained in the pre-processing phase Ph1, and the variation characteristic of the magnetic gap length corresponding to the rotational position of the rotor 72 is obtained. That is, control operation of the driving device 10 will be described on the premise that the variation characteristic of the magnetic gap length corresponding to the rotational position of the rotor 72 is obtained.

For example, it is assumed that the (instantaneous) magnetic gap length in the group 3 at a certain rotational position is smaller than the magnetic gap lengths in the group 1, the group 2, and the group 4. In this case, the current input value to the coils belonging to the group 3 is set to be smaller than the current input values to the coils belonging to the group 1, the group 2, and the group 4 at the rotational position (instantaneous time).

When time further elapses and the position at which the magnetic gap length becomes small is located in a different group, the setting of the current value of each group is changed in accordance with the magnetic gap length (rotational position) that changes with time such that the current value of the different group is set to be smaller than those of the other groups. By performing the control in this way, it is possible to implement the electric rotating machine system 100 that reduces vibration and noise caused by the dynamic eccentricity.

Note that, also in Embodiment 6, an example is shown in which the voltage acquisition unit 2 of the magnetic gap length estimating device 1 is connected to each of the twenty connection lines 9 connecting the four-group five-phase winding and the electric rotating machine 7. However, as in Embodiment 5 in which the magnetic gap length estimating device 1 is used alone, when the minimum number of line-to-line voltage waveforms with which a Lissajous curve can be created can be acquired, the magnetic gap length estimating device 1 can estimate the direction in which the magnetic gap length is displaced, so that the control parameters can be calculated.

Note that the magnetic gap length estimating device according to Embodiment 1, Embodiment 3, and Embodiment 5 and the driving device for the electric rotating machine according to Embodiment 2, Embodiment 4, and Embodiment 6 may be configured with hardware 1000 provided with a processor 1001 and a storage device 1002 as shown in FIG. 25. Although not shown, the storage device 1002 includes a volatile storage device such as a random access memory and a nonvolatile auxiliary storage device such as a flash memory. In addition, a hard disk as an auxiliary storage device may be provided instead of the flash memory. The processor 1001 executes a program input from the storage device 1002. In this case, the program is input from the auxiliary storage device to the processor 1001 via the volatile storage device. In addition, the processor 1001 may output data such as a calculation result to the volatile storage device of the storage device 1002, or may store the data in the auxiliary storage device via the volatile storage device.

### Other Variations

The magnetic gap length estimating device described in each of Embodiment 1, Embodiment 3, and Embodiment 5 estimates the magnetic gap length in the following respective manners. For the electric rotating machine 7 having six poles (electrode pairs: L=3), the magnetic gap length is estimated using the third-order component that is the fundamental wave and the second-order and fourth-order components that are the feature amounts of the dynamic eccentricity in a line-to-line voltage. For the electric rotating machine 7 having ten poles (electrode pairs: L=5), the magnetic gap length is estimated using the fifth-order component that is the fundamental wave and the fourth-order and sixth-order components that are the feature amounts of the dynamic eccentricity in a line-to-line voltage. For the electric rotating machine 7 having eight poles (electrode pairs: L=4), the magnetic gap length is estimated using the fourth-order component that is the fundamental wave and the third-order and fifth-order components that are the feature amounts of the dynamic eccentricity in a line-to-line voltage. That is, for an electric rotating machine 7 having L pole pairs as another electric rotating machine 7, the magnetic gap length estimating device 1 of the present application can estimate the magnetic gap length using the L±P-th order harmonic components of a line-to-line voltage.

Further, when an m-group n-phase k-th coil in the electric rotating machine with M groups, N phases, and each phase constituted by K coils is denoted by C (m, n, k), 1≤m≤M, 1≤n≤N, and 1≤k≤K are satisfied. Then, the coils are arranged counterclockwise in the order of C(1, 1, 1), C(1, 1, 2), . . . , C(1, 1, K), C(1, 2, 1), . . . , C(1, 2, K), . . . , C(1, N, K), C(2, 1, 1), . . . , C(M, N, K). That is, the coils are arranged counterclockwise in ascending order of the coil number, in ascending order of the phase number, and in ascending order of the group number.

As a result, the difference in the amplitude of the voltage waveform between phases due to the imbalance in the magnetic gap length increases. When the difference in the amplitude of the voltage waveform between phases increases, the L±P-th order harmonic components of each line-to-line voltage used for the estimation of the magnetic gap length also increases, and thus it is possible to further increase the estimation accuracy of the magnetic gap length. Further, even when the electric rotating machine system 100 including the electric rotating machine 7 in which the eccentricity occurs in the manufacturing process is constructed, the electric rotating machine 7 can be driven by modifying the control parameters in accordance with the estimated gap length. Therefore, it is possible to reduce the vibration and the noise caused by the dynamic eccentricity.

Although the coils are arranged counterclockwise in the ascending order of the coil number (k), in the ascending order of the phase number (n), and in the ascending order of the group number (m), the same effect can be obtained when the coils are arranged clockwise. That is, the same effect can be obtained by arranging the coils such that the coil number (k), the phase number (n), and the group number (m) are sequentially changed along the circumferential direction.

Although various exemplary embodiments are described in the present application, various features, aspects, and functions described in one or more embodiments are not inherent in an application of the contents disclosed in a particular embodiment, and can be applicable alone or in their various combinations to each embodiment. Accordingly, countless variations that are not illustrated are envisaged within the scope of the art disclosed in the specification of the present application. For example, the case where at least one component is modified, added or omitted, and the case where at least one component is extracted and combined with a component disclosed in another embodiment are included.

As described above, according to the magnetic gap length estimating device 1 of the present application, the magnetic gap length estimating device includes the voltage acquisition unit 2 to acquire a line-to-line induced voltage induced in connection lines 9 between the electric rotating machine 7 having a plurality of groups of coils when coils of a plurality of phases are set as one group and an inverter 8 for driving the electric rotating machine 7, the estimation information creation unit 3 to create estimation information corresponding to the electric rotating machine 7 for estimating the magnetic gap length from a waveform of the line-to-line induced voltage when the electric rotating machine 7 is rotated in an unload state, and the instantaneous gap length estimation unit 4 to estimate the magnetic gap length at an instantaneous time from an instantaneous value of the line-to-line induced voltage and the estimation information. Therefore, it is possible to estimate the magnetic gap length without requiring additional equipment such as a current sensor and a current load, and to suppress vibration and noise caused by the variation.

In particular, the estimation information creation unit 3 includes the spectrum analysis unit 341 to convert the waveform into an amplitude and a phase for each of frequencies, the frequency analysis unit 342 to extract amplitudes and phases of a fundamental wave component and L±P-th order harmonic components of the line-to-line induced voltage from the amplitude and the phase that are converted for each frequency, P being an integer of 1 or more, L being the number of pole pairs of the stator 71 of the electric rotating machine 7, and the estimation information calculation unit 35 to calculate the estimation information from the extracted amplitudes and phases of the fundamental wave component and the L±P-th order harmonic components. Therefore, the instantaneous value of the magnetic gap length, which varies with time, can be easily estimated.

The voltage acquisition unit 2 acquires at least one location of a line-to-line induced voltage between the same phases of different groups among the line-to-line induced voltages. Therefore, the magnetic gap length can be estimated with high accuracy using a simple configuration.

Further, since the driving device 10 for the electric rotating machine includes the magnetic gap length estimating device 1 described above and a control parameter calculation unit 5 to calculate a control parameter of the inverter 8 on the basis of the magnetic gap length at an instantaneous time estimated by the magnetic gap length estimating device 1, it is possible to estimate the magnetic gap length without requiring additional equipment such as a current sensor and a current load, and to suppress vibration and noise caused by the variation.

Furthermore, since the electric rotating machine system 100 of the present application includes the above-described driving device 10 for the electric rotating machine, the inverter 8 controlled by the driving device 10 for the electric rotating machine, and the electric rotating machine 7 driven by the inverter 8, it is possible to suppress vibration and noise caused by the variation in the magnetic gap length.

In the electric rotating machine 7, the coils of each group are arranged at a phase difference of a mechanical angle obtained by dividing 360 degrees by the number of groups. Therefore, the accuracy of detecting the variation (eccentricity) of the magnetic gap length is improved.

In this case, the coils are arranged such that the coil number, the phase number, and the group number sequentially change along the circumferential direction. Therefore, the detection accuracy is further improved.

Furthermore, the coils are configured in a Y-connection in each group in which the coils are connected in series for each phase. Therefore, the detection accuracy is further improved.

In this case, the neutral points of the groups in the Y-connection in the electric rotating machine 7 are electrically connected to each other. Therefore, offset voltages between the neutral points are prevented from being mixed into the detected voltage waveforms, and the detection accuracy is improved.

Further, coils between the same phases of different groups among the coils are arranged in the positions in the circumferential direction to have 0 degrees in the electrical phase difference. Therefore, the fundamental wave component of the line-to-line voltage between the same phases of different groups is canceled, and the detection accuracy is improved.

As described above, according to the magnetic gap length estimating method of the present application, the method includes the step (pre-processing phase Ph1) of rotating the electric rotating machine 7 having a plurality of groups of coils when the coils of a plurality of phases are set as one group, by one or more rotations at a constant rotation speed in an unloaded state, acquiring a waveform of the line-to-line induced voltage induced in the connection lines 9 between the electric rotating machine 7 and the inverter 8 for driving the electric rotating machine 7, and creating estimation information corresponding to the electric rotating machine 7 for estimating the magnetic gap length, and the step (detection phase Ph2) of estimating the magnetic gap length at an instantaneous time from an instantaneous value of the line-to-line induced voltage and the estimation information. Therefore, it is possible to estimate the magnetic gap length without requiring additional equipment such as a current sensor and a current load, and to suppress vibration and noise caused by the variation.

The step (pre-processing phase Ph1) of creating estimation information includes the step (step S11) of measuring waveforms of the line-to-line voltages between different phases of the same group and between the same phases of different groups as the line-to-line induced voltages, the steps (step S12 to step S15) of estimating a variation amount of the magnetic gap length and a relative displacement direction of the magnetic gap length with respect to a magnetic pole position by extracting the fundamental wave components and the L±P-th order harmonic components of the line-to-line voltages from the measured waveforms, P being an integer of 1 or more, L being the number of pole pairs of the stator 71 of the electric rotating machine 7, and the step (step S16) of creating a Lissajous curve as the estimation information from the waveforms. Therefore, it is possible to easily obtain accurate estimation information for estimating the magnetic gap length without requiring additional equipment such as a current sensor and a current load.

The step (detection phase Ph2) of estimating the instantaneous magnetic gap length includes the step (step S21) of measuring instantaneous values of the line-to-line voltages between different phases of the same group and between the same phases of different groups as the line-to-line induced voltages, the step (step S22 to step S23) of comparing arctangents of the instantaneous values with the estimated information, and the step (step S24) of estimating an instantaneous absolute displacement direction of the magnetic gap length on a basis of a result of the comparison. Therefore, the instantaneous value of the magnetic gap length, which varies with time, can be easily estimated without requiring additional equipment such as a current sensor and a current load. By using the result, the electric rotating machine 7 can be driven and controlled in real time so as to suppress vibration and noise caused by the variation of the magnetic gap length.

### DESCRIPTION OF REFERENCE NUMERALS AND SIGNS

1: magnetic gap length estimating device, 10: driving device for electric rotating machine, 100: electric rotating machine system, 2: voltage acquisition unit, 3: estimation information creation unit, 341: spectrum analysis unit, 342: frequency analysis unit, 35: estimation information calculation unit, 4: instantaneous gap length estimation unit, 5: control parameter calculation unit, 7: electric rotating machine, 8: inverter, 9: connection lines, L: the number of pole pairs, α: displacement direction.

1.-10. (canceled)

11. A magnetic gap length estimating method comprising steps of:
rotating an electric rotating machine having a plurality of groups of coils when coils of a plurality of phases are set as one group, by one or more rotations at a constant rotation speed in an unloaded state;
acquiring a waveform of a line-to-line induced voltage induced in connection lines between the electric rotating machine and an inverter for driving the electric rotating machine;
creating estimation information corresponding to the electric rotating machine for estimating a magnetic gap length; and
estimating the magnetic gap length at an instantaneous time from an instantaneous value of the line-to-line induced voltage and the estimation information.

12. The magnetic gap length estimating method according to claim 11, wherein the step of creating estimation information comprises steps of:
measuring waveforms of line-to-line voltages between different phases of the same group and between the same phases of different groups as the line-to-line induced voltages;
estimating a variation amount of the magnetic gap length and a relative displacement direction of the magnetic gap length with respect to a magnetic pole position by extracting fundamental wave components and L±P-th order harmonic components of the line-to-line voltages from the waveforms, P being an integer of 1 or more, L being the number of pole pairs of a stator of the electric rotating machine; and
creating a Lissajous curve as the estimation information from the waveforms.

13. The magnetic gap length estimating method according to claim 11, wherein the step of estimating the instantaneous magnetic gap length comprises:
measuring instantaneous values of the line-to-line voltages between different phases of the same group and between the same phases of different groups as the line-to-line induced voltages;
comparing arctangents of the instantaneous values with the estimated information; and
estimating an instantaneous absolute displacement direction of the magnetic gap length on a basis of a result of the comparison.

14. The magnetic gap length estimating method according to claim 12, wherein the step of estimating the instantaneous magnetic gap length comprises:
measuring instantaneous values of the line-to-line voltages between different phases of the same group and between the same phases of different groups as the line-to-line induced voltages;
comparing arctangents of the instantaneous values with the estimated information; and
estimating an instantaneous absolute displacement direction of the magnetic gap length on a basis of a result of the comparison.

15. A magnetic gap length estimating device comprising:
a voltage acquisition circuitry to acquire a line-to-line induced voltage induced in connection lines between an electric rotating machine having a plurality of groups of coils when coils of a plurality of phases are set as one group and an inverter for driving the electric rotating machine;
an estimation information creation circuitry to create estimation information corresponding to the electric rotating machine for estimating a magnetic gap length from a waveform of the line-to-line induced voltage when the electric rotating machine is rotated in an unload state; and
an instantaneous gap length estimation circuitry to estimate the magnetic gap length at an instantaneous time from an instantaneous value of the line-to-line induced voltage and the estimation information.

16. The magnetic gap length estimating device according to claim 15, wherein the estimation information creation circuitry includes a spectrum analyzer to convert the waveform into an amplitude and a phase in each of frequencies, a frequency analyzer to extract amplitudes and phases of a fundamental wave component and L±P-th order harmonic components of the line-to-line induced voltage from the amplitude and the phase that are converted in each frequency, P being an integer of 1 or more, L being the number of pole pairs of a stator of the electric rotating machine, and an estimation information calculator to calculate the estimation information from the extracted amplitudes and phases of the fundamental wave component and the L±P-th order harmonic components.

17. The magnetic gap length estimating device according to claim 15, wherein the voltage acquisition circuitry acquires at least one location of a line-to-line induced voltage between the same phases of different groups among the line-to-line induced voltages.

18. A driving device for an electric rotating machine comprising:
the magnetic gap length estimating device according to claim 15; and
a control parameter calculator to calculate a control parameter of the inverter on a basis of the magnetic gap length at an instantaneous time estimated by the magnetic gap length estimating device.

19. A driving device for an electric rotating machine comprising:
the magnetic gap length estimating device according to claim 16; and
a control parameter calculator to calculate a control parameter of the inverter on a basis of the magnetic gap length at an instantaneous time estimated by the magnetic gap length estimating device.

20. A driving device for an electric rotating machine comprising:
the magnetic gap length estimating device according to claim 17; and
a control parameter calculator to calculate a control parameter of the inverter on a basis of the magnetic gap length at an instantaneous time estimated by the magnetic gap length estimating device.

21. An electric rotating machine system comprising:
the driving device for the electric rotating machine according to claim 18;
the inverter controlled by the driving device for the electric rotating machine; and
the electric rotating machine driven by the inverter.

22. An electric rotating machine system comprising:
the driving device for the electric rotating machine according to claim 19;
the inverter controlled by the driving device for the electric rotating machine; and
the electric rotating machine driven by the inverter.

23. An electric rotating machine system comprising:
the driving device for the electric rotating machine according to claim 20;
the inverter controlled by the driving device for the electric rotating machine; and
the electric rotating machine driven by the inverter.

24. The electric rotating machine system according to claim 21, wherein the electric rotating machine includes a stator in which the coils of each group are arranged at a phase difference of a mechanical angle obtained by dividing 360 degrees by the number of groups.

25. The electric rotating machine system according to claim 24, wherein the coils are arranged such that a coil number, a phase number, and a group number sequentially change along a circumferential direction.

26. The electric rotating machine system according to claim 24, wherein the coils are configured in a Y-connection in each group in which the coils are connected in series for each phase.

27. The electric rotating machine system according to claim 25, wherein the coils are configured in a Y-connection in each group in which the coils are connected in series for each phase.

28. The electric rotating machine system according to claim 26, wherein neutral points of the groups in the Y-connection in the electric rotating machine are electrically connected to each other.

29. The electric rotating machine system according to claim 27, wherein neutral points of the groups in the Y-connection in the electric rotating machine are electrically connected to each other.

30. The electric rotating machine system according to claim 21, wherein coils between the same phases of different groups among the coils are arranged in positions in the circumferential direction to
have 0 degrees in an electrical phase difference.
